(19) United States
(12) Patent Application Publication
(10) Pub. No.: US 2023/0360928 A1
(43) Pub. Date: Nov. 9, 2023

(54) METHOD FOR MANUFACTURING SEMICONDUCTOR DEVICES AND CORRESPONDING SEMICONDUCTOR DEVICE

(71) Applicant: STMicroelectronics S.r.l., Agrate Brianza (MB) (IT)

(72) Inventors: Marco ROVITTO, Milano (IT); Dario VITELLO, Merate (LC) (IT)

(73) Assignee: STMicroelectronics S.r.l., Agrate Brianza (MB) (IT)

(21) Appl. No.: 18/140,290

(22) Filed: Apr. 27, 2023

(30) Foreign Application Priority Data
May 3, 2022 (IT) 102022000008891

(51) Int. Cl. H01L 21/56; H01L 21/48; H01L 23/00; H01L 23/495; H01L 23/498; H01L 21/768

(52) U.S. Cl. CPC H01L 21/565; H01L 21/4825; H01L 23/562; H01L 23/49513; H01L 23/49548; H01L 23/49827; H01L 21/76894; H01L 21/4842

(57) ABSTRACT

A semiconductor die is attached on a die mounting surface of a substrate. An insulating encapsulation of laser direct structuring (LDS) material is molded onto the substrate and the semiconductor die. The insulating encapsulation of LDS material has a front surface including a first portion and a second portion separated by gaps therebetween. Laser direct structuring processing is applied to the first portion of the front surface to structure in the encapsulation of LDS material electrically conductive formations including electrically conductive lines over the front surface and to the second portion of the front surface of the encapsulation of LDS material to form thereon a reinforcing warp-countering structure. The separation gaps are left exempt from laser direct structuring processing and the reinforcing warp-countering structure is electrically insulated from the electrically conductive lines by LDS material left exempt from laser direct structuring processing at the separation gaps.

### PRIORITY CLAIM

This application claims the priority benefit of Italian Application for Patent No. 102022000008891 filed on May 3, 2022, the content of which is hereby incorporated by reference in its entirety to the maximum extent allowable by law.

### TECHNICAL FIELD

The description relates to manufacturing semiconductor devices.

One or more embodiments may be applied to manufacturing integrated circuits (ICs).

### BACKGROUND

Various processes used in manufacturing semiconductor devices involve using molded strips including different materials.

These materials may exhibit different thermo-mechanical properties, and molded strips tend to warp when the molding process is completed.

When deformation of a molded strip becomes too large, various negative issues may arise.

For instance, singulating a molded substrate into individual pieces by a dicer may become difficult and/or plating processes or “second mold” processing may be undesirably affected.

These issues may become particularly evident in the case of material suited for laser direct structuring (LDS) methods and materials.

There is a need in the art to contribute in overcoming the drawbacks outlined in the foregoing.

### SUMMARY

One or more embodiments relate to a method.

One or more embodiments relate to a corresponding semiconductor device (an integrated circuit, for instance).

One or more embodiments involve forming, in a package including laser direct structuring (LDS) material, an electrically active metallization together with a dummy metallization configured to counter undesired warping.

One or more embodiments involve forming a leadframe-metallization-mold sandwich, which leads to a more balanced stress, with reduced strip warpage and improved manufacturability. No additional process steps are involved.

### BRIEF DESCRIPTION OF THE DRAWINGS

One or more embodiments will now be described, by way of example only, with reference to the annexed figures, wherein:

FIG. 1 is a cross-sectional view across a conventional semiconductor device;

FIG. 2 is a cross-sectional view across a type of semiconductor device to which embodiments of the present description can be applied;

FIGS. 3 to 9 are exemplary of various steps in manufacturing a semiconductor device according to embodiments of the present description; there, FIG. 6 corresponds to a plan view of the assembly of FIG. 5 reproduced on an enlarged scale; and

FIG. 10 shows certain possible details of embodiments of the present description.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The references used herein are provided merely for convenience and hence do not define the extent of protection or the scope of the embodiments.

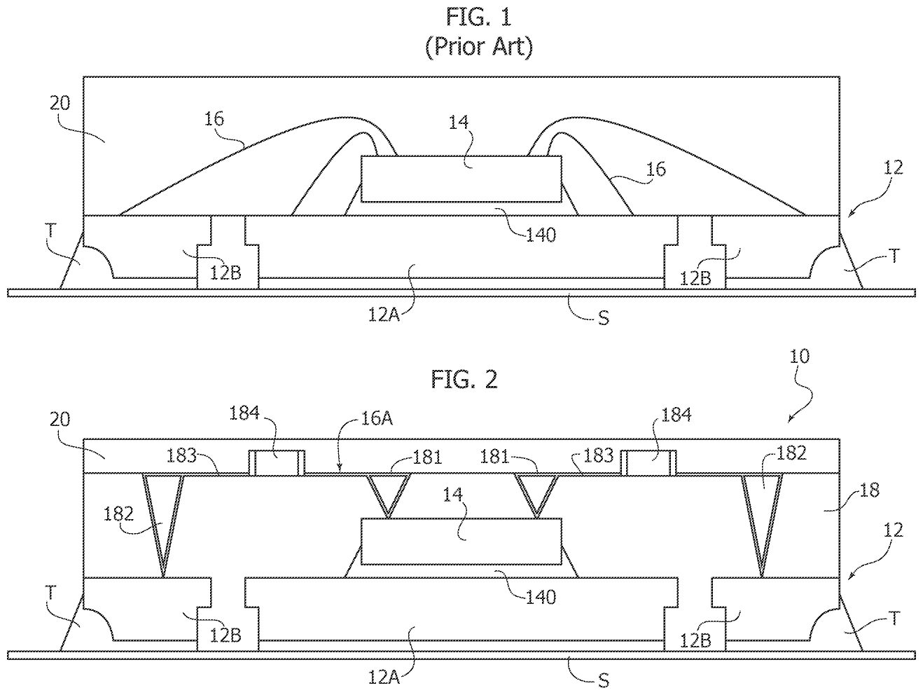

FIG. 1 shows a cross-sectional view across a conventional semiconductor device in a Quad-Flat No-leads (QFN) package.

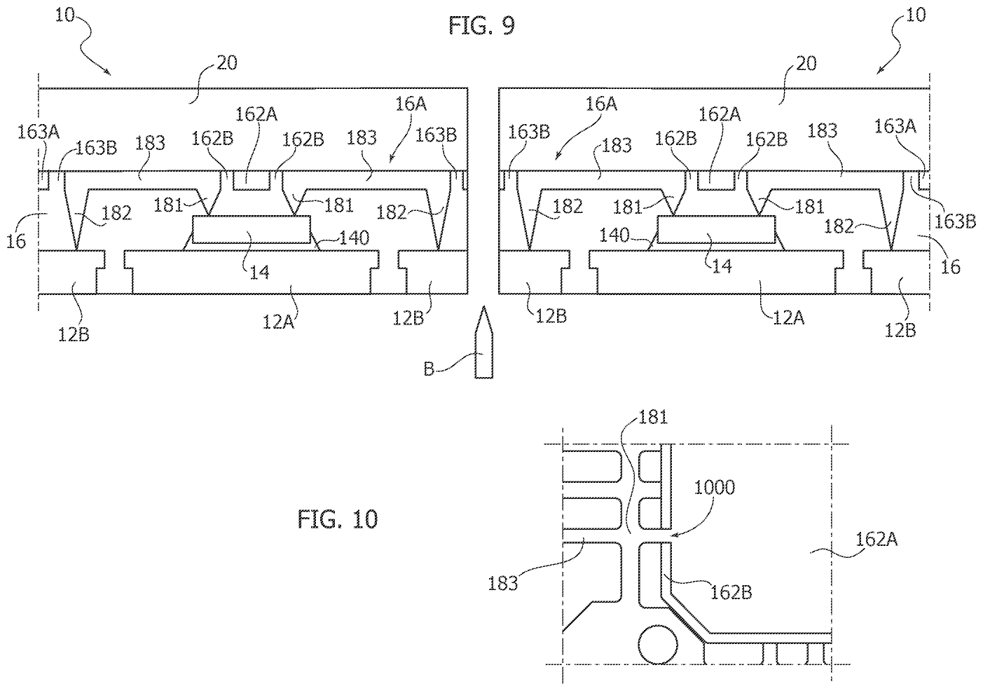

FIG. 1 (and FIG. 2 as well) refer for simplicity to a single device. In fact, semiconductor devices as considered herein are currently manufactured in an assembly flow of plural semiconductor devices that are manufactured simultaneously and finally separated into individual devices 10 via a singulation step as exemplified in FIG. 9.

FIG. 1 refers to a (single) device comprising a leadframe having one or more die pads 12A (only one is illustrated for simplicity) onto which a semiconductor integrated circuit chip or die 14 is mounted (attached using die attach material 140, for instance) with an array of leads 12B around the die pad 12A and the semiconductor chip or die 14.

As used herein, the terms integrated circuit chip/s and integrated circuit die/dice are regarded as synonymous.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the die or chip to other electrical components or contacts.

Essentially, a leadframe comprises an array of electrically-conductive formations (or leads, for example, 12B) that from an outline location extend inwardly in the direction of a semiconductor chip or die (for example, 14) thus forming an array of electrically-conductive formations from a die pad (for example, 12A) configured to have at least one semiconductor chip or die attached thereon. This may be via conventional means such as a die attach adhesive (a die attach film (DAF) 140, for instance).

A device as illustrated in FIG. 1 is configured to be mounted on a substrate S such as a printed circuit board (PCB), using solder material T, for instance.

For simplicity, in FIG. 1 (and FIG. 2 as well) a single die pad 12A is illustrated having a single chip 14 attached thereon. In various embodiments, plural chips 14 can be mounted on a single die pad 12A or plural die pads.

In FIG. 1 reference numeral 16 denotes a wire bonding pattern made of wires that electrically couple contact pads (not visible for scale reasons) at the top or front surface of the die 14 with selected ones of the leads 12B in the leadframe 12.

An encapsulation 20 of insulating material (an epoxy resin, for instance) is molded on the leadframe 12 having the chip 14 attached thereon to provide a protective package for the chip 14 (and the wire bonding pattern 16).

It is noted that the indication “No-leads” referred to a QFN device as depicted herein is not in contradiction with such a package comprising an array of leads such as 12B: in fact, the indication “No-leads” is related to the fact that a QFN package is substantially exempt from external (distal) tips of the leads in the leadframe 12 protruding from the encapsulation 20.

A leadframe 12 as illustrated in FIG. 1 can be of the pre-molded type, that is a type of leadframe comprising a sculptured metal (for example, copper) structure formed by etching a metal sheet and comprising empty spaces that are filled by a resin “pre-molded” on the sculptured metal structure.

All of the foregoing is conventional in the art, which makes it unnecessary to provide a more description herein.

Additionally, unless the context indicates otherwise, the disclosure of parts or elements provided in connection with FIG. 1 also applies to FIG. 2 and to the other figures: a corresponding description will not be repeated for brevity for each and every figure.

FIG. 2 is illustrative of the possibility of applying laser direct structuring (LDS) technology in replacing wire bonding technology in providing die-to-lead electrical coupling in a semiconductor device designated 10 as a whole.

Laser direct structuring (LDS), oftentimes referred to also as direct copper interconnection (DCI) technology, is a laser-based machining technique now widely used in various sectors of the industrial and consumer electronics markets, for instance for high-performance antenna integration, where an antenna design can be directly formed onto a molded plastic part.

In an exemplary process, the molded parts can be produced with commercially available insulating resins that include additives suitable for the LDS process; a broad range of resins such as polymer resins like PC, PC/ABS, ABS, LCP are currently available for that purpose. In LDS, a laser beam can be used to transfer (“structure”) a desired electrically-conductive pattern onto a plastic molding that may then be subjected to metallization to finalize a desired conductive pattern.

Metallization may involve electroless plating followed by electrolytic plating.

Electroless plating, also known as chemical plating, is a class of industrial chemical processes that creates metal coatings on various materials by autocatalytic chemical reduction of metal cations in a liquid bath.

In electrolytic plating, an electric field between an anode and a workpiece, acting as a cathode, forces positively charged metal ions to move to the cathode where they give up their charge and deposit themselves as metal on the surface of the work piece.

United States Patent Application Publication Nos. 2018/342453 A1, 2019/115287 A1, 2020/203264 A1, 2020/321274 A1, 2021/050226 A1, 2021/050299 A1, 2021/183748 A1, or 2021/305203 A1 (all incorporated herein by reference) are exemplary of the possibility of applying LDS technology in manufacturing semiconductor devices.

For instance, LDS technology facilitates replacing wires, clips or ribbons with lines/vias created by laser beam processing of an LDS material followed by metallization (growing metal such as copper via a plating process, for instance).

Referring to FIG. 2, an encapsulation 16 of LDS material can be molded onto the leadframe 12A, 12B having the semiconductor chip or die 14 mounted thereon.

As illustrated, the LDS encapsulation has, opposite the leadframe 12, a front or top surface 16A that is at least approximately flush with the front or top surface of the chip or die 14.

Electrically conductive die-to-lead coupling formations can be provided (as discussed in the commonly assigned applications cited in the foregoing, for instance) in the LDS material 16 (once consolidated, for example, via thermosetting).

As illustrated in FIG. 2, these die-to-lead coupling formations comprise: first through mold vias (TMVs) 181 that extend through the LDS encapsulation 16 between the top (front) surface 16A of the LDS encapsulation 16 and electrically-conductive pads (not visible for scale reasons) at the front or top surface of the chip or die 14; second through mold vias (TMVs) 182 that extend through the LDS encapsulation 16 between the top (front) surface 16A of the LDS encapsulation 16 and corresponding leads 12B in the leadframe; and electrically-conductive lines or traces 183 that extend at the front or top surface 16A of the LDS encapsulation 16 and electrically couple selected ones of the first vias 181 with selected ones of the second vias 182 to provide a desired die-to-lead electrical connection (routing) pattern between the chip or die 14 and the leads 12B.

Electrical components 184 (for example, passive components such as resistors, for instance) may be possibly arranged along one or more of the lines or traces 183.

Providing the electrically conductive die-to-lead formations 181, 182, and 183 essentially involves: structuring these formations in the LDS material 16, for instance, laser-drilling (blind) holes therein at the desired locations for the vias 181, 182; and growing electrically conductive material (a metal such as copper, for instance) at the locations previously activated (structured) via laser beam energy.

As illustrated in FIG. 2, a further encapsulation material 20 (this can be non-LDS material, for example, a standard epoxy resin as is the case of the encapsulation 20 of FIG. 1) can be molded onto the die-to-lead formations 181, 182, and 183 to complete the device package.

Further details on LDS processing as discussed in the foregoing can be derived from the United States Patent Application Publication references referred to in the foregoing, for instance.

Briefly, using LDS technology, through mold vias (TMVs) 181, 182 and traces 183 are created to electrically interconnect one or more semiconductor dice 14 to a leadframe (leads 12B) thereby replacing conventional wire bonding used for that purpose.

With LDS technology, the interconnection is created using laser structuring (to create vias and lines or traces) and metal plating is used to fill the laser-structured formations with metal such as copper.

United States Patent Publication Nos. 2023/0035445 and 2023/0035470 (corresponding to Italian patent applications 102021000020537 and 102021000020540, respectively), which are incorporated herein by reference, disclose the possibility of extending the use of LDS processing from producing die-to-lead coupling formations as discussed in the foregoing to producing die-to-die coupling formations.

While disclosed for simplicity in connection with forming vias in die-to-lead coupling formations, the examples herein can thus be advantageously applied in connection with forming vias in die-to-die coupling formations.

United States Patent Publication No. 2023/0035470 discloses the possible use of a laser-induced forward transfer (LIFT) process in growing electrically conductive material such as metal at locations of an LDS material previously structured (activated) via laser beam energy.

The acronym LIFT denotes a deposition process where material from a donor tape or sheet is transferred to an acceptor substrate (here, the LDS material) facilitated by laser pulses.

General information on the LIFT process can be found, for instance, in P. Serra, et al.: “Laser-Induced Forward Transfer: Fundamentals and Applications”, in Advanced Materials Technologies/Volume 4, Issue 1 (incorporated herein by reference).

The rest of the present description will refer for simplicity to LDS technology as currently applied today (namely: laser activation of certain locations of a LDS material to structure therein vias and/or traces followed by metal deposition via electroless/electrolytic metal growth to facilitate electrical conductivity of the structured formations). However, various embodiments may include laser activation of certain locations of a LDS material followed—advantageously after electroless metal deposition—by LIFT processing (transfer of electrically conductive material) to facilitate electrical conductivity of the structured formations.

A semiconductor device 10 as considered herein may be a semiconductor device 10 a Quad-Flat No-leads (QFN) package.

In the following, mounting a single integrated circuit chip or die 14 on the substrate 12 will be discussed for simplicity; in various embodiments, plural chips or dice 14 can be mounted on the substrate (leadframe) 12.

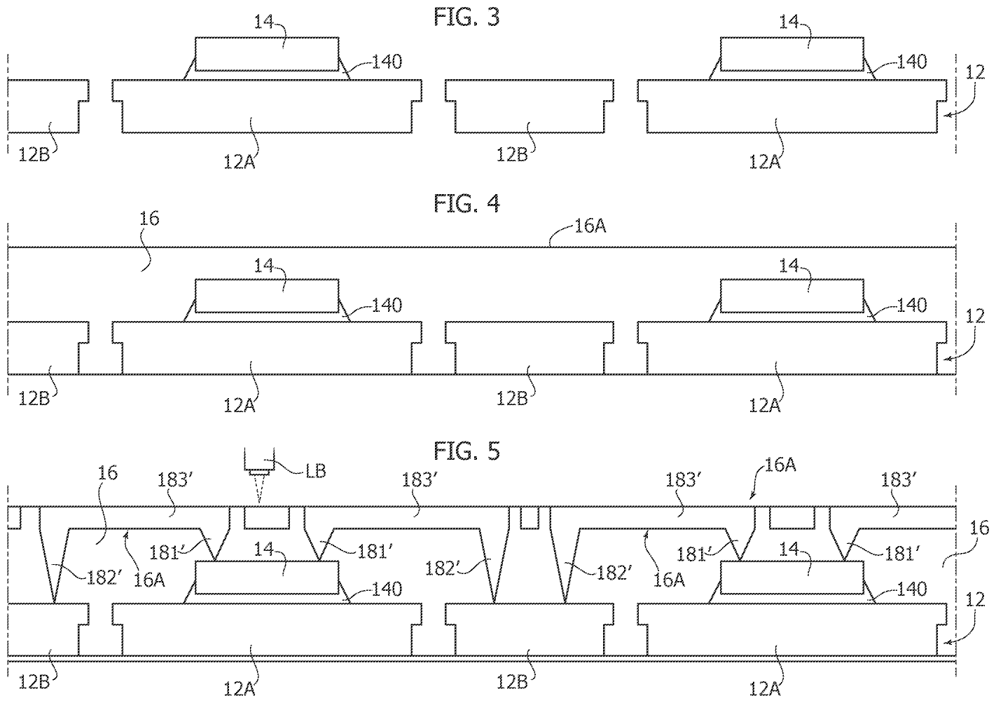

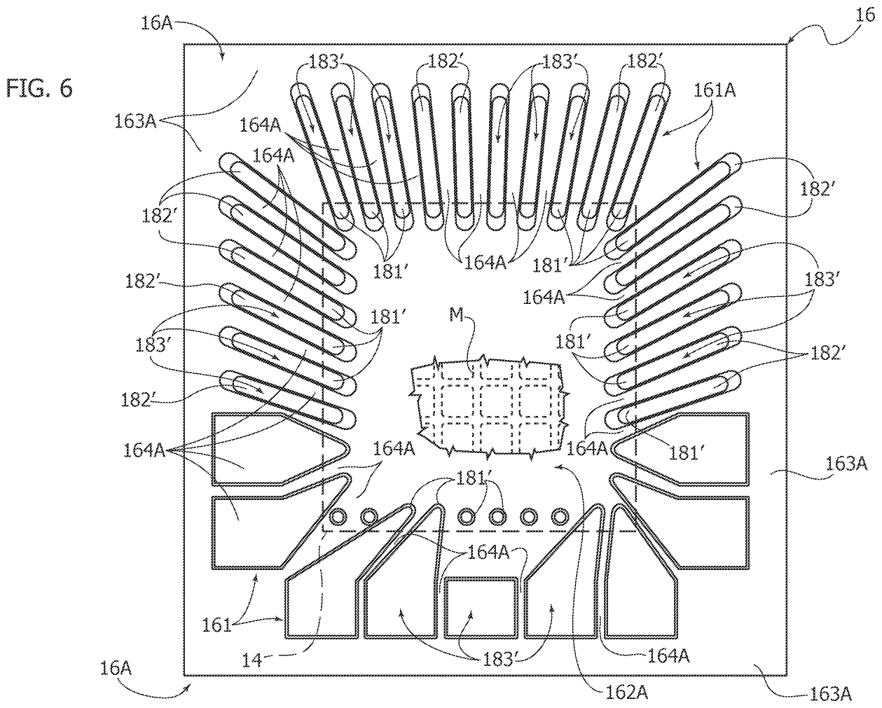

FIGS. 3 to 9 (with FIG. 6 essentially corresponding to a plan view of the structure of FIG. 5) are exemplary of various steps in manufacturing a semiconductor device such as the device 10.

As noted, current production processes of semiconductor devices involve a chain or string of devices manufactured simultaneously to be finally separated into individual devices via a “singulation” step (for example, cutting the chain or string between adjacent devices via a blade B as shown in FIG. 9).

Unless the context indicates differently, the individual steps illustrated in FIGS. 3 to 9 can be performed in a manner known to those of skill in the art, which makes it unnecessary to provide a more detailed description of these individual steps.

It will be otherwise appreciated that the sequence of steps of FIGS. 3 to 9 is merely exemplary insofar as: one or more steps illustrated in FIGS. 3 to 9 can be omitted, performed in a different manner (with other tools, for instance) and/or replaced by other steps; additional steps may be added; and one or more steps can be carried out in a sequence different from the sequence illustrated.

FIG. 3 is exemplary of the provision of a (essentially standard) leadframe 12 including die pads 12A and arrays of leads 12B with semiconductor integrated circuit chips or dice 14 attached at a first (front or top) surface of the die pads 12A. This may occur, as conventional in the art, via die attach material 140.

Devices 10 (each) comprising a single die pad 12A having attached thereon a single die of chip 14 are illustrated here for simplicity. In various embodiments, devices such as the devices 10 considered herein can include plural semiconductor chips or dice 14 arranged at a die pad 12A; likewise, the leadframe 12 may include plural die pads 12A intended to be included in a single device 10.

FIG. 4 is exemplary of an encapsulation 16 of LDS material (of any type known to those of skill in the art and suited for use in the context consider herein) molded (for example, via compression molding) onto the structure of FIG. 3.

To that effect, the leadframe 12 may be supported by a plate or tape (to be finally removed), which is not visible in the figures for simplicity and ease of explanation.

FIG. 4 is thus exemplary of encapsulating the substrate 12 with the semiconductor chip 14 arranged thereon in an encapsulation 16 of laser direct structuring (LDS) material.

As illustrated, the encapsulation 16 has a first surface toward the leadframe 12 and a second (front or top) surface 16A opposed the first surface, that is, facing away from the leadframe 12. As illustrated, the surface 16A is spaced with respect the front or top surface of the dice 14.

FIG. 5 is exemplary of the application of laser beam energy (as schematically represented by the reference LB) to “structure” in the LDS material of the encapsulation 16: first through mold vias (TMVs) 181 that extend through the LDS encapsulation 16 between the top (front) surface 16A of the LDS encapsulation 16 and electrically conductive pads (not visible for scale reasons) at the front or top surface of the chips or dice 14; second through mold vias (TMVs) 182 that extend through the LDS encapsulation 16 between the top (front) surface 16A of the LDS encapsulation 16 and corresponding leads 12B in the leadframe; and electrically conductive lines or traces 183 that extend at the front or top surface 16A of the LDS encapsulation 16 and electrically couple selected ones of the first vias 181 with selected ones of the second vias 182 to provide a desired die-to-lead electrical connection pattern (routing) between the chip or die 14 and the leads 12B.

As noted, electrical components (for example, passive components such as resistors, for instance) can be arranged along one or more of the lines or traces 183. Such (non-mandatory) components are not explicitly visible in the figure for simplicity.

In FIG. 5, reference numbers with prime marks (namely 181′, 182′ and 183′) are used to designate the result of laser beam structuring (activating) the LDS material 16 with the aim of providing the first through mold vias 181, the second through mold vias (TMVs) 182 and the electrically conductive lines or traces 183.

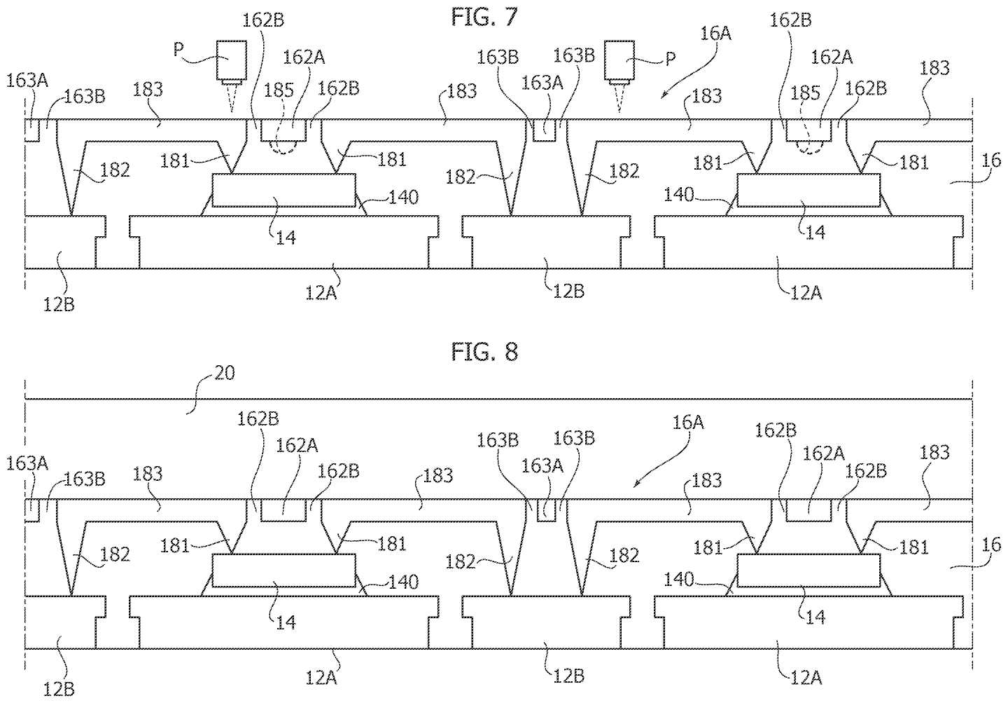

According to current LDS technology, such structuring is completed via plating steps as exemplified by reference at P in FIG. 7 to facilitate electrical conductivity of the vias 181, 182 and the lines or traces 183.

Using LDS technology, through mold vias (TMVs) 181, 182 and traces 183 are created to electrically interconnect one or more semiconductor dice 14 to a leadframe (leads 12B) thereby replacing conventional wire bonding used for that purpose.

As noted previously: the possibility exists of extending the use of LDS processing from die-to-lead coupling formations as discussed in the foregoing to die-to-die coupling formations; and laser-induced forward transfer (LIFT) process can be used as an alternative to plating (electrolytic, for instance) in growing electrically conductive material such metal (for example, copper) at those locations of an LDS material previously structured (activated) via laser beam energy.

Consequently, the embodiments are not limited to solutions involving (only) die-to-lead coupling formations and/or to solutions where electrolytic processes are used to grow electrically conductive material at those locations of an LDS material previously structured (activated) via laser beam energy.

Tin plating (for example, 100 microns, not visible for simplicity) can be provided at the back or bottom surface of the die pad 12 (opposite the chip or die 14) to facilitate soldering on the substrate S.

As illustrated in FIG. 8, a further encapsulation material 20 (this can be non-LDS material, for example, a standard epoxy resin) can be molded onto the electrically conductive formations 181, 182, and 183 to complete the device package.

The strip-like structure formed in the steps illustrated in FIGS. 3 to 8 can then be subjected to “singulation” (via a blade B, for instance) to provide individual devices 10: see, for example, FIG. 9.

As discussed in the introductory portion to this description, molded strips including different materials may tend to warp due to the different thermo mechanical properties of the materials included therein.

When deformation or warping of such a molded strip becomes too large, various issues may arise.

For instance, singulating a molded substrate into individual pieces by a dicer may become difficult: when a molded strip is held on a sawing machine by vacuum, a warpage in excess of, for example, 1.5 mm (strip warpage can be measured as the maximum distance between a contact plane and the bottom strip surface within a measurement area) may militate against adequate holding (fixing) of leadframes on the machine.

Performing a plating process in mass production may likewise become critical: for instance, a molded strip may become stuck in the groove between two guide wheels due to high warpage, which causes leadframe deformation.

A high strip warpage after a first molding step (for example, LDS material) may adversely affect a second (for example, non-LDS) molding process.

As noted, these issues may become particularly evident if LDS technology is used to create interconnections using laser structuring (to create vias and lines or traces) followed by metal growth used to fill the laser-structured formations.

These issues may be attempted to be addressed by resorting to different approaches.

For instance, one might try to adjust various parameters such as the mold temperature, curing time or transfer pressure and/or to apply weights during post mold curing (PMC) or thermal treatment after PMC.

This approach is inevitably demanding and involves (too) many trials.

Another approach might involve modifying the mold equipment, which is quite expensive.

Still another approach might involve using different materials for the mold resin (with a different coefficient of thermal expansion or CTE, shrinkage, filler content, Tg and modulus), the die attach material (again CTE, modulus, curing) or the leadframe (using stiffer material and/or an increased thickness).

This approach turns out to be (at least) time consuming and again expensive.

Examples as discussed herein are based on the recognition that, rather than making the situation worse, LDS technology may be beneficial in addressing and solving these issues.

Observation of FIG. 6, for instance, shows that in examples as described herein, LDS processing (laser structuring/activation) of the LDS material 16 is not limited to the locations where the vias 181, 182 and the traces 183 are formed (locations designated 181′, 182′ and 183′ in FIG. 6).

In examples as described herein, LDS processing is not limited to a first (here, roughly annular and square) portion/region 161A of the front surface 16A of the insulating encapsulation 16 of LDS material where the electrically conductive traces 183′, 183 are formed coupled to proximal ends of selected ones of the through mold vias 181′, 181 and 182′, 182.

As depicted in FIG. 6, in solutions as described herein, LDS processing (laser structuring/activation) of the LDS material 16 is applied also to a second portion of the front surface 16A that comprises: a second (here, roughly square) central region 162A of the front surface 16A of the insulating encapsulation 16 of LDS material, lying inwardly of the region 161A; a third (here, roughly annular and square) outer region 163A of the front surface 16A of the insulating encapsulation 16 of LDS material, lying outwardly of the region 161A; and a fourth region 164A of the front surface 16A of the insulating encapsulation 16 of LDS material which roughly corresponds to the region 161A and includes elongated areas of the surface 16A that are interdigitated with (and generally electrically insulated from) the electrically conductive traces 183′, 183.

The wording “interdigitated” indicates that the elongated areas in the region 164A extends like fingers interleaved with the electrically conductive traces 183′, 183.

Stated otherwise, in solutions as described herein, a (quite) substantial portion of the front surface 16A of the LDS material 16 is subjected to LDS processing (laser structuring/activation and growth of electrically conductive material)) both: at the (first) portion 161A where the electrically conductive traces 183′, 183 are formed coupled to proximal ends of selected ones of the through mold vias 181′, 181 and 182′, 18; and at the (second) portion comprising the regions 162, 163A, 164A.

It is noted that the first portion and second portion of the surface 16A subjected to LDS processing (structuring/activation by laser and growth of electrically conductive material at the structured/activated locations) are non-overlapping, with the regions 162A, 163A lying internally and externally of the region 161A and the areas of the region 164A being interdigitated with the electrically conductive traces 183′, 183 in the region 161A.

That is, in solutions as described herein, the front surface 16A of the LDS material 16 is almost entirely subjected to LDS processing with the exception of (usually thin) gap areas surrounding the electrically conductive traces.

This is visible in FIG. 5 and more evidently highlighted in FIGS. 7 to 9 where (first) portions of the LDS material 16 that are made electrically conductive via LDS processing to provide the electrically conductive formations including the through mold vias 181, 182 and the traces 183 are separated from (second) portions (for example, 162A, 163A) that are likewise subjected to LDS processing by insulating gaps (for example, 162B, 163B).

In those gap areas (for example, 162B, 163B) the LDS material of the encapsulation 16 is not activated/structured and thus maintains its insulating behavior thus facilitating electrical insulation (and creepage), for example, around the conductive traces 183′, 183 as desired.

To summarize, examples as presented herein involve providing an insulating encapsulation 16 of LDS material having, opposite the laminar substrate 12, a front surface 16A comprising a first portion 161A and a second portion 162A, 163A, 164A; as visible (for example, in FIG. 5) the first portion (for example, 161A) and the second portion (for example, 162A, 163A, 164A) are mutually separated by separation gaps therebetween.

Advantageously, these separation gaps are (very) thin or narrow so that the first portion and the second portion make up practically the whole area of the front surface 16A (with the exception of the area fraction occupied by the gaps therebetween).

In examples as presented herein, laser direct structuring processing (for example, LB, P) is applied to the front surface 16A in a selective manner, by: applying laser direct structuring processing (for example, LB, P) to the first portion 161A of the front surface 16A to structure therein (functionally active) electrically conductive formations comprising the through mold vias 181, 182 as well as the electrically conductive lines 183; applying laser direct structuring processing (for example, LB, P) to the second portion 162A, 163A, 164A of the front surface 16A to structure therein a reinforcing warp-countering structure extending over the second portion 162A, 163A, 164A of the front surface 16A; and leaving exempt from laser direct structuring processing (that is, refraining from applying laser direct structuring processing LB, P to) the separation gaps (for example, 162B, 163B in FIGS. 7 to 9) between the first portion 161A and the second portion 162A, 163A, 164A of the front surface 16A.

In that way, the reinforcing warp-countering structure (that per se is not expected to play any functional role in terms of electrical conductivity) formed over the second portion 162A, 163A, 164A of the front surface 16A is electrically insulated from the electrically conductive formations (vias 181, 182 and traces 183) by LDS material left exempt from said laser direct structuring processing (and thus remaining essentially non-conductive) at separation gaps such as 162B, 163B.

Metal such as copper grown, for example, via electroless plating followed by electrolytic deposition or by LIFT transfer resulting in growth of electrically conductive material—only— at the laser activated regions (and not at the gaps such as 162B, 163B) thus leads to the formation of: electrically conductive through mold vias 181, 182 plus traces 183 providing a desired routing pattern between selected ones of the vias 181, 182 at the (first) region 161A; and a reinforcing (stiffening) structure countering strip warping that comprises the metal grown at the second and third regions 162A and 163A plus at the fourth region 164A of the front surface 16A (in an interdigitated manner with the electrically conductive traces 183′, 183) of the insulating encapsulation 16.

In examples as illustrated herein, such a reinforcing or stiffening structure may have, for instance, a thickness between about 10 and about 500 microns.

As used herein “about”, refers to a value as accurate as the method used to measure it.

In examples as illustrated herein, such a reinforcing or stiffening structure is substantially continuous (that is, plate-like) at the regions 162A and 163A.

As used herein, “substantially”, applied to the reinforcing structure, will indicate such a technical feature being produced within the technical tolerance of the method used to manufacture it.

In various embodiments (as schematically illustrated in dashed lines and indicated by reference M at the center of FIG. 6) such a reinforcing or stiffening structure can be mesh-like (that is, reticular) at the regions 162A and 163A.

As schematically represented and indicated by the reference 185 (only) in FIG. 7, such a structure countering strip warping may include stiffening ribs 185 (formed by partial laser ablation of the LDS material 16 just like the vias 181, 182) providing further rigidity to the reinforcing structure countering strip warping.

The further encapsulation material 20 molded onto the electrically conductive formations 181, 182, and 183 (and thus also onto the regions 162A and 163A— plus the region 164A of the reinforcing structure interdigitated with the formations 183 and insulated therefrom at gaps such as 162B and 163B left exempt from LDS processing) was found to be beneficial in creating a sandwich arrangement of increased stiffness including the reinforcing structure between the encapsulation 16 and further encapsulation material 20.

For instance, a reinforcing/stiffening structure as described herein having a thickness of about 100 microns was found to provide a 40% reduction of strip warpage prior to molding the (second) encapsulation 20 and a 60% reduction of strip warpage after molding the (second) encapsulation 20.

For the sake of completeness, it is noted that United States Patent Application Publication No. 2022/0199477 (corresponding to Italian patent application 102020000031244), incorporated herein by reference, discloses molding onto a semiconductor chip or die an encapsulation of LDS material and applying laser direct structuring processing to the LDS material to provide, in addition to at least one metal via through the encapsulation, a heat-spreader metal pad at the outer surface of the encapsulation.

Even leaving other factors apart, such a metal pad is not insulated with respect to the via(s), does not necessarily extend over the front surface of the LDS encapsulation in such a way to provide an effective stiffening action against undesired strip warping and is not expected to co-operate with further encapsulation material molded onto the electrically conductive formations formed in the LDS material to provide a stiff sandwich structure.

More to the point, the surface portion where such a metal pad is provided essentially overlaps with the portion where the via(s) are provided, and does not include any region where such a metal pad is interdigitated with respect to the traces between the vias.

The same reasoning also applies to electrically conductive RF shields formed on IC packages.

This is in contrast with the examples presented herein where the stiffening (or stress balancing) metal structure is formed in the regions 162A, 163A, and 164A as a dummy portion of an otherwise electrically functional metallization level (the vias/traces in the region 161A), thus integrating stress balancing metallization (dummy) with a co-planar electrically-active metallization.

FIG. 10 is otherwise illustrative of the fact that in certain examples, conductive bridges (typically sacrificial) such as the bridge 1000 can be provided between the “electrically functional” metallization level (for example, the traces in the region 161A) and one or more of the regions 162A, 163A, 164A of the “stress balancing” dummy metallization in order to facilitate these latter in acting as electrodes during the electrolytic growth of metal over the locations of the surface 16A of the LDS encapsulation previously subjected to laser beam activation (structuring).

It is noted that these (temporary) bridges do not derogate from the reinforcing warp-countering structure being electrically insulated from said electrically conductive formations 181, 182, 183 by LDS material of the encapsulation 16 left exempt from laser direct structuring processing at separation gaps such as 162B, 163B.

Also, such electrically conductive bridges can be avoided in the case LIFT technology is resorted to for metal growth (for example, over an electroless-grown metal layer).

Without prejudice to the underlying principles, the details and embodiments may vary, even significantly, with respect to what has been described by way of example only without departing from the scope of protection.

The claims are an integral part of the technical teaching provided herein in respect of the embodiments.

The extent of protection is defined by the annexed claims.

1. A method, comprising:
attaching a semiconductor die on a substrate;
molding an insulating encapsulation of laser direct structuring (LDS) material onto the substrate and the semiconductor die, wherein the insulating encapsulation of LDS material has, opposite the substrate, a front surface comprising a first portion and a second portion;
applying laser direct structuring processing to the first portion of the front surface to structure therein electrically conductive formations comprising vias and electrically conductive lines extending over the first portion of the front surface and connecting to said semiconductor die;
applying laser direct structuring processing to the second portion of the front surface to structure therein a reinforcing warp-countering structure extending over the second portion of the front surface of the encapsulation of LDS material; and
leaving exempt from laser direct structuring processing separation gaps between the first portion and the second portion of the front surface of the encapsulation of LDS material;
wherein said reinforcing warp-countering structure is electrically insulated from said electrically conductive lines by LDS material of said encapsulation left exempt from laser direct structuring processing at said separation gaps.

2. The method of any claim 1, wherein at least one region of the second portion of the front surface of the encapsulation of LDS material includes the reinforcing warp-countering structure interdigitated with the electrically conductive lines extending over the first portion of the front surface of the encapsulation of LDS material.

3. The method of claim 1, wherein said reinforcing warp-countering structure comprises a plate-like structure.

4. The method of claim 1, wherein said reinforcing warp-countering structure comprises a meshed structure.

5. The method of claim 1, wherein said reinforcing warp-countering structure comprises stiffening ribs.

6. The method of claim 1, wherein the reinforcing warp-countering structure has a thickness between about 10 and about 500 microns.

7. The method of claim 1, further comprising molding a further encapsulation on the front surface of the encapsulation of LDS material, wherein the reinforcing warp-countering structure is sandwiched between the encapsulation of LDS material and the further encapsulation molded thereon.

8. The method of claim 1, wherein applying laser direct structuring processing to the encapsulation of LDS material comprises:
applying laser beam energy to the encapsulation of LDS material to selectively structure therein laser-structured locations; and
providing electrically conductive material at the laser-structured locations by one of:
electroless deposition of electrically conductive material;
electrolytic deposition of electrically conductive material; and
laser-induced forward transfer, LIFT of electrically conductive material.

9. A semiconductor device, comprising:
a semiconductor die attached on a substrate;
an insulating encapsulation of laser direct structuring (LDS) material molded onto the substrate and the semiconductor die, wherein the insulating encapsulation of LDS material has, opposite the laminar substrate, a front surface comprising a first portion and a second portion;
wherein the encapsulation of LDS material includes:
laser direct structured locations at the first portion of the front surface of the encapsulation of LDS material that provide electrically conductive formations comprising electrically conductive lines extending over the first portion of the front surface of the encapsulation of LDS material and electrically connecting to the semiconductor die; and
laser direct structured locations at the second portion of the front surface of the encapsulation of LDS material that provide a reinforcing warp-countering structure formation extending over the second portion of the front surface of the encapsulation of LDS material;
wherein separation gaps exist between the first portion and the second portion of the front surface of the encapsulation of LDS material which are left exempt from laser direct structuring processing; and
wherein said reinforcing warp-countering structure is electrically insulated from said electrically conductive lines by LDS material of said encapsulation left exempt from said laser direct structuring processing at said separation gaps.

10. The semiconductor device of claim 9, wherein the reinforcing warp-countering structure is interdigitated with the electrically conductive lines.

11. The semiconductor device of claim 9, wherein the reinforcing warp-countering structure comprises, over a least one region of the second portion of the front surface of the encapsulation of LDS material, a plate-like structure.

12. The semiconductor device of claim 9, wherein the reinforcing warp-countering structure comprises, over a least one region of the second portion of the front surface of the encapsulation of LDS material, a meshed structure.

13. The semiconductor device of claim 9, wherein the reinforcing warp-countering structure comprises, over a least one region of the second portion of the front surface of the encapsulation of LDS material, stiffening ribs.

14. The semiconductor device of claim 9, wherein the reinforcing warp-countering structure has a thickness between about 10 and about 500 microns.

15. The semiconductor device of claim 9, further comprising a further encapsulation molded on the front surface of the encapsulation of LDS material, wherein the reinforcing warp-countering structure is sandwiched between the encapsulation of LDS material and the further encapsulation molded thereon.
